(19) United States
(12) Patent Application Publication
(10) Pub. No.: US 2014/0254615 A1
(43) Pub. Date: Sep. 11, 2014

(54) LASER DEVICE

(71) Applicant: CANON KABUSHIKI KAISHA, Tokyo (JP)

(72) Inventors: Ryota Sekiguchi, Tokyo (JP); Toshihiko Ouchi, Machida-shi (JP)

(73) Assignee: CANON KABUSHIKI KAISHA, Tokyo (JP)

(21) Appl. No.: 14/195,926

(22) Filed: Mar. 4, 2014

(30) Foreign Application Priority Data
Mar. 11, 2013 (JP) 2013-048167

(51) Int. Cl. H01S 5/22

(52) U.S. Cl. CPC H01S 5/22
USPC 372/4; 372/45.01

(57) ABSTRACT

A laser device comprises a waveguide including a resonance structure for causing electromagnetic waves to resonate. The waveguide by turn comprises a gain medium for generating electromagnetic waves, a first negative permittivity medium arranged electrically in contact with the gain medium, a second negative permittivity medium arranged electrically in contact with the gain medium at the side opposite to the first negative permittivity medium so as to dispose the gain medium between the first and second negative permittivity mediums, and lateral structures of a positive permittivity medium arranged to be in contact with lateral surfaces of the gain medium and sandwiched between the first and second negative permittivity mediums. The waveguide has a section in which the width w of the gain medium sandwiched between the lateral structures is not greater than twice of the thickness h of the lateral structures sandwiched between the first and second negative permittivity mediums.

### BACKGROUND OF THE INVENTION

1. Field of the Invention

The present invention relates to a laser device. Particularly, the present invention relates to a current injection type laser device for typically generating electromagnetic waves (to be also referred to as terahertz waves hereinafter) in a frequency band within the frequency region extending between the millimeter wave range and the terahertz range (between 30 GHz and 30 THz). More particularly, the present invention relates to a current injection type laser device having a waveguide for propagating surface plasmons.

2. Description of the Related Art

Oscillators based on energy level transitions (inter-sub-band transitions) of carriers in a same energy band, which may be the conduction band or the valence band, and formed by machining quantum cascade lasers and tunneling diodes to realize waveguides are known as new type semiconductor laser oscillators. Recently, there has been arising a new demand for electromagnetic wave resources in the terahertz range that are believed to be useful for bio-sensing. As a result, efforts have been and being paid to develop quantum cascade lasers with emphasis on the longer wavelength side for oscillation wavelengths and also to develop waveguide-shaped tunneling diode oscillators with emphasis on the higher frequency side for oscillation frequencies have been and are being paid.

Benjamin S. Williams, Nat. Photonics. Vol. 1 (2007), 97 discloses several techniques for causing quantum cascade lasers to oscillate in the terahertz range. One of the disclosed techniques is for forming a metal-metal waveguide by sandwiching a semiconductor gain medium between two metal pieces. The metal functions as a negative permittivity medium whose real part of permittivity is negative in this frequency band. At this time, guided modes to be guided by the clads of the negative permittivity mediums are electromagnetic waves to which polarization oscillations of charge carriers in the negative permittivity mediums have contributed. Such polarization oscillations of charge carriers are referred to as surface plasmons. Since no diffraction limit exists in surface plasmons, much of the mode intensity can be confined to the gain medium. Laser oscillations with an oscillation frequency of 1.2 THz (oscillation wavelength λ=250 μm) are achieved by the above-described technique.

Japanese Patent No. 4857027 discloses a structure formed by sandwiching a semiconductor gain medium and a dielectric as lateral structures between two negative permittivity mediums (each of which comprises a metal or a densely doped semiconductor as a constituting material).

At this time again, while guided modes to be guided by the clads or the negative permittivity mediums are also surface plasmons, the waveguide loss can be effectively reduced by introducing dielectric lateral structures. Thus, a waveguide-shaped oscillator with an oscillation frequency of 0.3 THz (oscillation wavelength λ=1,000 μm) that can be oscillated, for instance, by means of a tunneling diode is realized by using such a technique.

However, further characteristic improvements are required to laser devices in the frequency region between the millimeter wave range and the terahertz range. The required improvements include improvements of the cross sectional profiles of waveguides. Benjamin S. Williams, Nat. Photonics. Vol. 1 (2007), 97, however, does not contain any description on the width direction of waveguide. While Japanese Patent No. 4857027 takes the width direction of waveguide into consideration, the Patent Literature only discloses that the width of a waveguide is not greater than the oscillation wavelength. Thus, there has not been any sufficient knowledge on the widths of waveguides that is vital for improving the net gain (the difference obtained by subtracting the waveguide loss from the nominal gain) in conventional laser oscillators.

### SUMMARY OF THE INVENTION

In view of the above-identified problem, therefore, the object of the present invention is to provide a technique of optimizing the cross sectional profile of the waveguide of a device such as a laser device in a frequency band within the frequency region extending between the millimeter wave range and the terahertz range.

In one aspect of the present invention, there is provided a laser device comprising a waveguide including a resonance structure for causing electromagnetic waves to resonate; the waveguide including: a gain medium for generating electromagnetic waves; a first negative permittivity medium having a negative real part of permittivity relative to the electromagnetic waves, the first negative permittivity medium being arranged to be electrically in contact with the gain medium; a second negative permittivity medium having a negative real part of permittivity relative to the electromagnetic waves, the second negative permittivity medium being arranged to be electrically in contact with the gain medium at the side opposite to the first negative permittivity medium with respect to be the gain medium such that the gain medium is disposed between the first and second negative permittivity mediums; and lateral structures having a positive real part of permittivity relative to the electromagnetic waves arranged to be in contact with lateral surfaces of the gain medium and sandwiched between the first and second negative permittivity mediums, wherein the waveguide has a section in which the width w of the gain medium sandwiched between the lateral structures is not greater than twice of the thickness h of the lateral structures sandwiched between the first and second negative permittivity mediums.

Further features of the present invention will become apparent from the following description of exemplary embodiments with reference to the attached drawings.

### BRIEF DESCRIPTION OF THE DRAWINGS

FIG. 1 is a schematic cross sectional view of the first embodiment of laser device according to the present invention, showing the structure thereof.

FIGS. 2A, 2B and 2C are schematic cross sectional views of embodiments obtained by modifying the first embodiment of laser device, showing the structures thereof.

FIG. 3 is a schematic cross sectional view of the second embodiment of laser device according to the present invention, showing the structure thereof.

FIG. 4 is a schematic cross sectional view of the third embodiment of laser device according to the present invention, showing the structure thereof.

FIGS. 5A and 5B are top views of the fourth embodiment of laser device according to the present invention, showing the structure thereof.

FIGS. 6A, 6B and 6C are a schematic cross sectional view and graphs showing the results of calculations for determining the waveguide loss (attenuation constant) a and the wave-number in the direction of propagation (propagation constant) β of the laser device of Example 1.

### DESCRIPTION OF THE EMBODIMENTS

A laser device according to the present invention is characterized in that the gain medium has a section disposed between the two side surfaces thereof with width w not greater than twice of the thickness h of the lateral structures sandwiched between the first and second negative permittivity mediums. As a result of the present invention, the cross sectional profile of the waveguide of a laser device can be optimized to improve the net gain unlike the prior art that has not been able to do so.

The problem of the cross sectional profile of a waveguide can be discussed in terms of electric circuit by replacing the electromagnetic wave gain of the gain medium of a known laser device with a negative differential conductance Gd (<0). In the case of a quantum cascade laser, the gain can be expressed as negative optical conductivity σ(λ), which is a function of wavelength λ. Gd(λ) and σ(λ) have a proportional relation. In the case of a tunneling diode, Gd in DC (direct current) may be extended to the frequency region between the millimeter wave band and the terahertz wave band because the negative conductance Gd does not change significantly in the frequency region between DC and the terahertz wave band. Such a replacement gives a good approximation particularly when the surface plasmon mode that is maintained in a waveguide is a single mode.

When the width of a waveguide is relatively small and hence good for only single mode propagations, a proportional relation of electromagnetic wave gain to −Gd holds true so that the ratio between them gives a constant of proportionality. The waveguide loss can be decomposed into the electric resistance Rs per unit length of the waveguide in the longitudinal direction and the conductance Gp per unit length of the waveguide in the thickness direction. Then, the waveguide loss α can be expressed by the formula shown below as the first approximation, thanks to the theory of distributed constant circuit:

α=Rs/Zc+GpZc.

where Zc is the characteristic impedance of the waveguide, which is proportional to the ratio of the electric field to the magnetic field of the electromagnetic wave propagating through the waveguide. Since the negative permittivity mediums of the waveguide in a known laser device are formed by materials showing a relatively large electric conductivity selected from metals and densely doped semiconductors, the second term at the right side of the above formula may be taken for Gp to Gd (<0). This term takes a negative value. The waveguide loss α has a unit of m¹and, when the absolute value of the second term exceeds the absolute value of the first term at the right side, α indicates a negative gain and hence a net electromagnetic wave gain. While Rs is determined by the conductor losses of the negative permittivity mediums, Zc can be adjusted by adjusting the cross sectional profile of the waveguide. Thus, there is a room for optimization in Zc.

The characteristic impedance Zc can be expressed by the formula shown below by using the inductance Ls per unit length of the waveguide in the longitudinal direction and the capacitance Cp per unit length of the waveguide in the thickness direction:

Zc=√(Ls/Cp).

In conventional laser devices, Ls is inversely proportional to the waveguide width w and Cp is proportional to the waveguide width w so that Zc ∝ 1/w holds true (∝ means “is proportional to”).

In a similar manner, the components of the waveguide loss α are defined in terms of dependency on waveguide width w to obtain the formulas shown below.

Case 1) when the gain medium is sandwiched by the negative permittivity mediums without being accompanied by lateral structures:

Rs ∝1/w;

Rs/Zc ∝ const (i.e., the first term at the right side is constant regardless of w);

Gd ∝ w; and

GdZc ∝ const (i.e., the second term at the right side is constant regardless of w).

Thus, any scale merit of optimizing the waveguide width w is hardly conceivable from the viewpoint of the first approximation.

Case 2) when both the gain medium and the lateral structures are sandwiched between the negative permittivity mediums:

Rs=const;

Rs/Zc ∝ w (i.e., the first term at the right side is proportional to w);

Gd ∝ w; and

GdZc ∝ const (i.e., the second term at the right side is constant regardless of w).

Thus, a smaller waveguide width w provides a scale merit of reducing Rs/Zc and hence the net electromagnetic gain can be increased accordingly. More accurately, while the dependency on w of Rs may vary depending on detailed structure, the dependency is lower than the first order of w (and the dependency on w approaches the nil order although Rs does not become constant) and hence the same conclusion will be reached. The present invention is for optimizing the cross sectional profile of the waveguide of a laser device on the basis of the qualitative discussions made above in terms of electric circuit. Now, several embodiments of the present invention will be given below.

### First Embodiment

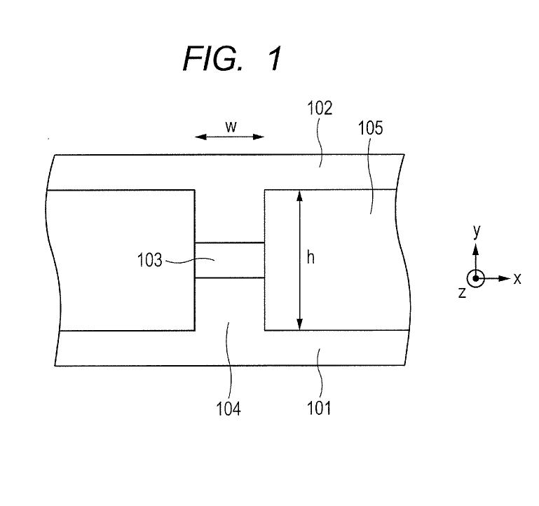

The first embodiment of laser device according to the present invention will be described below by referring to FIG. 1. FIG. 1 is a schematic cross sectional view of the waveguide of the first embodiment of laser device. In FIG. 1, the waveguide extends in the z direction (the direction perpendicular to the plane of the drawing). The z direction is the longitudinal direction of the waveguide and also shows the direction in which electromagnetic waves are propagated. The x direction is the width direction of the waveguide, while the y direction is the thickness direction of the waveguide.

In the first embodiment shown in FIG. 1, reference symbols 101 and 102 denote negative permittivity mediums in an oscillation frequency band within the frequency region extending between the millimeter wave band and the terahertz band. Each of the negative permittivity mediums comprises a metal and/or a densely doped semiconductor as a constituting material. Reference symbol 103 denotes a gain medium for generating electromagnetic waves in the above-identified frequency band. The negative permittivity mediums 101 and 102 are arranged at the opposite sides of the gain medium 103 so as to sandwich the gain medium 103 between them. A semiconductor multilayer film structure that provides a gain as a result of current injection may typically be adopted for the gain medium 103. The gain medium 103 is sandwiched between the negative permittivity mediums 101 and 102 and also electrically held in contact with the negative permittivity mediums 101 and 102 so that an electric current may be injected into the gain medium 103 by way of the negative permittivity mediums 101 and 102. A voltage that is supplied from an external electric field application means (not shown) is applied between the top and the bottom of the gain medium 103 by way of the negative permittivity mediums 101 and 102. Thus, an electric current can be injected into the gain medium 103 in this way. The negative permittivity mediums 101 and 102 are respectively the clad of the first negative permittivity medium and the clad of the second negative permittivity medium and a surface plasmon mode can be propagated in the z direction in the waveguide. Reference symbol 105 denotes a positive permittivity medium having a positive real part of permittivity. The positive permittivity medium may be formed by using a dielectric or air, which is in fact an air bridge.

The positive permittivity medium 105 forms lateral structures, which are arranged adjacently relative to the lateral surfaces of the gain medium and also sandwiched between the negative permittivity mediums 101 and 102 just like the gain medium.

At least one of the negative permittivity mediums 101 and 102 of this embodiment includes a rib-shaped part 104 projecting toward the gain medium 103 in the area having a width equal to the width of the gain medium 103. Of the cross sectional profile of the waveguide, the width w of the waveguide is defined as the distance between the lateral surfaces of the gain medium 103 as observed in the x direction. The height of the lateral structures that are formed by the positive permittivity medium 105 sandwiched between the negative permittivity mediums 101 and 102 as observed in the y direction is expressed by h.

In the instance of this embodiment, the electric resistance Rs of the waveguide in the longitudinal direction is determined by the parts of the negative permittivity mediums 101 and 102 that have a large size in the width direction and hence Rs=const. holds true. The value of the negative differential conductance Gd of the waveguide that is proportional to the electromagnetic wave gain of the gain medium is determined by the width w of the waveguide and Gd ∝ w holds true. The inductance Ls of the waveguide in the longitudinal direction thereof is rather determined by the height h of the lateral structures and hence the dependency thereof on the width w of the waveguide is relatively small. The capacitance per unit length Cp of the waveguide is determined by the width w of the waveguide because the gain medium 103 is made of semiconductor showing a relatively high permittivity. Therefore, the characteristic impedance Zc can roughly be expressed by formula Zc ∝ √/(h/w). Now, the components of the waveguide loss α=Rs/Zc+GpZc can be redefined as follow.

Rs=const;

Rs/Zc ∝√(w/h);

Gd ∝ w; and

GdZc ∝ √(h/w).

The structure dependency here differs from the above discussion because the height h of the lateral structures is taken into consideration. However, the conclusion is the same as the above-described one because, when the width w of the waveguide is smaller, Rs/Zc is smaller and GdZc is greater so that the net electromagnetic wave gain can be increased again. More specifically, Rs/Zc having a positive value becomes smaller while the absolute value of GdZc having a negative value becomes greater to consequently reduce the waveguide loss α (namely reduce the value of α when the value is positive or increase the absolute value of α when the value is negative) and hence increase the net electromagnetic wave gain. When the height h of the lateral structures is specifically defined as in this embodiment, the width w of the waveguide is preferably not greater than the height h of the lateral structures because then the net gain can effectively be increased. To broaden the allowable range, the width w of the waveguide may well be not greater than twice of the height h of the lateral structures. Differently stated, the waveguide is provided with a gain medium having a section disposed between the two lateral surfaces thereof with a width w not greater than the thickness h or twice of the thickness h of the lateral structures sandwiched between the first and second negative permittivity mediums. The width of the gain medium may be not greater than the thickness h or twice of the thickness h over the entire length of the resonance structure thereof.

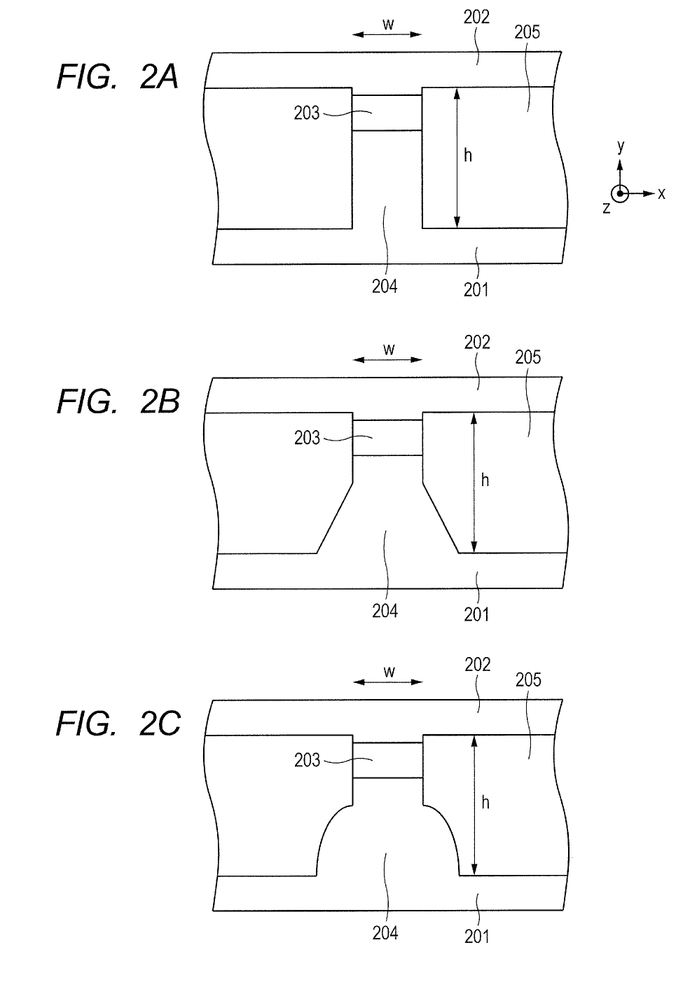

Waveguides having respective cross sectional views as shown in FIGS. 2A through 2C may be realizable as modifications to the first embodiment. In the above-described arrangement, the position of the gain medium 103 in the thickness direction of the waveguide may arbitrarily be selected. For example, the gain medium 203 may be arranged at a position that is eccentrically disposed toward the second negative permittivity medium 202 as shown in FIG. 2A or alternatively eccentrically disposed toward the first negative permittivity medium 201. Furthermore, the profile of the rib-shaped part of the either of the clads of the negative permittivity mediums may arbitrarily be defined. While the profile depends on the extent of leakage of magnetic lines of force directed from the gain medium 203 toward the lateral structures 205 and only has a minor effect, the rib may not necessarily be rectangular in a lateral view as shown in FIG. 2A. Namely, the rib may alternatively be a frust-conical rib 204 as shown in FIG. 2B or a barrel-shaped rib 205 as shown in FIG. 2C, or any arbitrary shapes.

### Second Embodiment

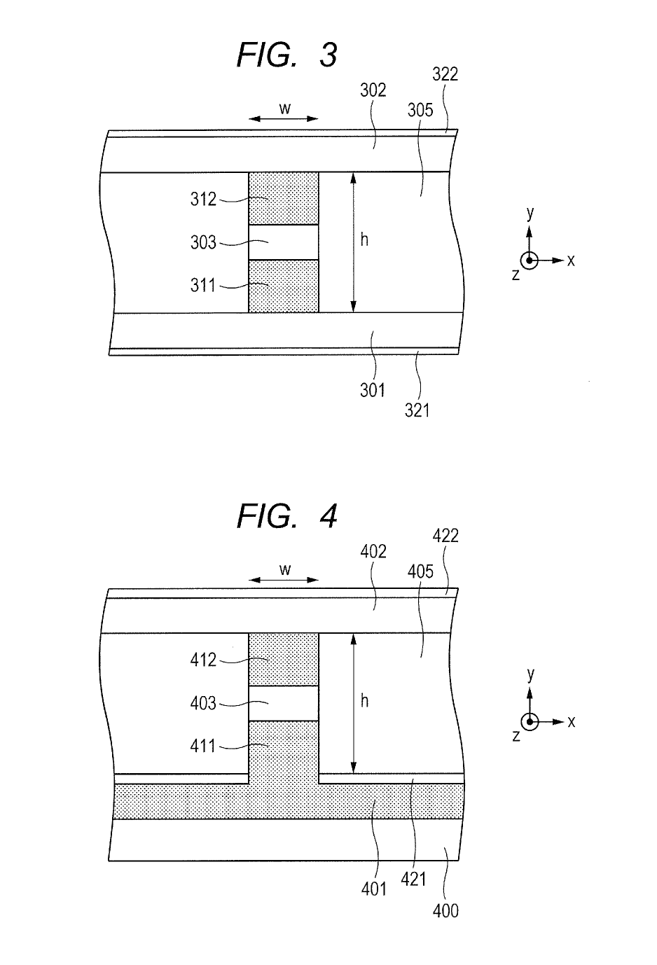

Now, the second embodiment of laser device according to the present invention will be described below by referring to FIG. 3. FIG. 3 is a schematic cross sectional view of the second embodiment of laser device. In FIG. 3, the waveguide extends in the z direction just like the waveguide of the first embodiment.

This embodiment is an embodiment that is made to show a higher actual adaptability than the first embodiment. In FIG. 3, reference symbols 311 and 312 denote negative permittivity mediums that are held in contact with gain medium 303 and each of which comprises a densely doped semiconductor as a constituting material. Reference symbols 301 and 302 denote negative permittivity mediums that are held in contact respectively with the negative permittivity mediums 311 and 312 of the densely doped semiconductor materials. The negative permittivity mediums 301 and 302 are made of a metal. The use of a metal is based on two reasons. One is for easy preparation and the other is for allowing a large value to be selected for the height h of the lateral structures 305 and providing a high degree of freedom of choice for the waveguide width w (≦h or ≦2h). A semiconductor multilayer film structure such as a quantum cascade laser, a tunneling diode or a resonant tunneling diode may typically be adopted for the gain medium 303. Since the negative permittivity mediums 311 and 312 are made of densely doped semiconductor, a multilayer structure of the negative permittivity medium 311, the gain medium 303 and the negative permittivity medium 312 can be formed with ease by continuous film formation or some other means. The negative permittivity medium 311, the gain medium 303 and the negative permittivity medium 312 can be made to have the same width w by adopting semiconductor materials that show substantially the same etching selection ratio for them so that they can be formed with ease by means of dry etching or wet etching. Note, however, a metal bonding process is normally required for realizing such a structure.

What is important for this embodiment is to structurally realize a constant Rs (the electric resistance in the longitudinal direction) as described above. To do so, electromagnetic waves need to be made to penetrate into the parts of the negative permittivity mediums 301 and 302 that show a large width in the width direction. Metals have a small penetration depth, whereas semiconductors have a large penetration depth in the oscillation frequency band of this embodiment. In view of these properties, a constant Rs can be realized more easily by using semiconductor than by using metal for the parts of the ribs 311 and 312 of the negative permittivity mediums. Densely doped semiconductors are employed for the ribs 311 and 312 in order to broaden the selectable range for the height h of the lateral structures 305. Typically, a carrier density of about 1×10¹⁹cm⁻³ is preferably selected.

This embodiment is provided with two electrodes 321 and 322 for injecting an electric current into the gain medium 303 by way of the metal-made negative permittivity mediums 301 and 302. The device of this embodiment can be operated for laser oscillations by connecting the two electrodes 321 and 322 to a voltage source (not shown).

### Third Embodiment

Now, the third embodiment of laser device according to the present invention will be described below by referring to FIG. 4. FIG. 4 is a schematic cross sectional view of the third embodiment of laser device. In FIG. 4, the waveguide extends in the z direction just like the waveguide of the first embodiment.

This embodiment is also an embodiment that is made to show a higher actual adaptability than the first embodiment. In FIG. 4, reference symbol 400 denotes an electro-conductive semiconductor substrate. Preferably, the carrier density of the substrate 400 is made to be not less than 1×10¹⁸cm⁻³. A semiconductor material that is densely doped with carriers is employed for the negative permittivity medium 401. In this embodiment, the semiconductor layer 401 desirably has a thickness greater than the penetration depth in the oscillation frequency band. For example, a semiconductor member having a thickness of several μm (e.g., 2 μm, 3 μm) and a carrier density of 1×10²⁰cm⁻³ is preferably employed. The metal 421 operates both as a clad for the negative permittivity medium and also as an electrode. The above-described arrangement is a suitable exemplar arrangement that can be prepared with ease and at the same time reduce the leakage of electric lines of force directed downward from the gain medium 403. The metal 402, the semiconductors 411 and 412 that are densely doped with carriers, the gain medium 403 and the electrode 422 are the same as or similar to their counterparts of the second embodiment. BCB (benzocyclobutene) that is a dielectric showing a relatively low loss and a low permittivity in the frequency region between the millimeter wave band and the terahertz band may be used for the positive permittivity medium 405.

In this embodiment, the substrate 400, the negative permittivity mediums 401 and 411, the gain medium 403, the negative permittivity medium 412 (the part of the second negative permittivity medium electrically held in contact with the gain medium) are all semiconductors. Such a multilayer structure can be formed on the semiconductor substrate 400 with ease by means of a semiconductor hetero epitaxial growth technique. Furthermore, no metal bonding process is required here.

### Fourth Embodiment

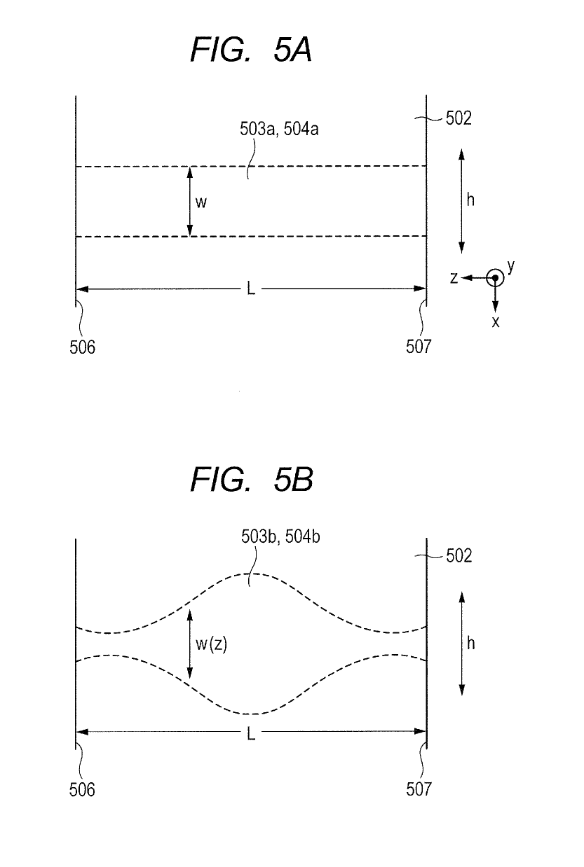

Now, the fourth embodiment of laser device according to the present invention will be described below by referring to FIGS. 5A and 5B. FIGS. 5A and 5B schematically illustrate this embodiment, showing two alternative configurations of waveguide with different top views. The waveguide extends in the z direction and the end facets thereof are formed by cutting the waveguide.

This embodiment shows an exemplar arrangement that can be provided along the direction of propagation of surface plasmons of the first embodiment and the laser cavity thereof is a Fabry-Perot cavity, which is sandwiched between the end facets of the waveguide of the embodiment produced by cutting the waveguide. Electromagnetic waves are made to be standing waves by utilizing reflections from the end facets. Differently stated, the waveguide is provided at least with two end facets in the direction of propagation of electromagnetic waves to form a resonance structure so as to produce standing waves out of electromagnetic waves by utilizing reflections from the end facets. The gain medium 503a and the rib 504a of the negative permittivity medium that are laid one on the other in the top views have respective cross sectional profiles that are the same as those of their counterparts of the first embodiment. Reference symbols 506 and 507 denote the end facets. If the length between the end facet 506 to the other end facet 507 is L and the magnitude of the wave-number in the direction of propagation for a surface plasmon mode is β, the oscillation wavelength is made selectable by making integer times of π/β agree with L as is well known in the field of semiconductor laser technology. Since the integer times are typically between 1 and about 100 times, the typical value for L is between tens of several μm and several mm.

When the height h of the lateral structures is also defined in this embodiment, the width w of the waveguide is preferably not greater than the height h of the lateral structures for the net gain −α. FIG. 5A shows an example in which the width of the waveguide is constant over the entire length of the waveguide in the direction of propagation and hence in the z direction. This example provides a large net gain −α over the entire length of the waveguide in the direction of propagation. However, a small waveguide width does not contribute much to improvement of the power output of the laser oscillator. For this reason, an arrangement of making the width w(z) of the waveguide vary as a function of the direction of propagation z as shown in FIG. 5B is conceivable. In FIG. 5B, the gain medium 503b and the negative permittivity medium 504b are also laid one on the other. The illustrated structure is advantageous for optimizing the net gain and the oscillator output because the net gain −α shows a large value over the span where w(z)≦h (or ≦2h) holds true, whereas a large current injection can be realized over the span where w(z)>h (or >2h) holds true. The metal 502 is the same as that of the second embodiment.

Now, the laser device in an example will specifically be described below.

### EXAMPLE 1

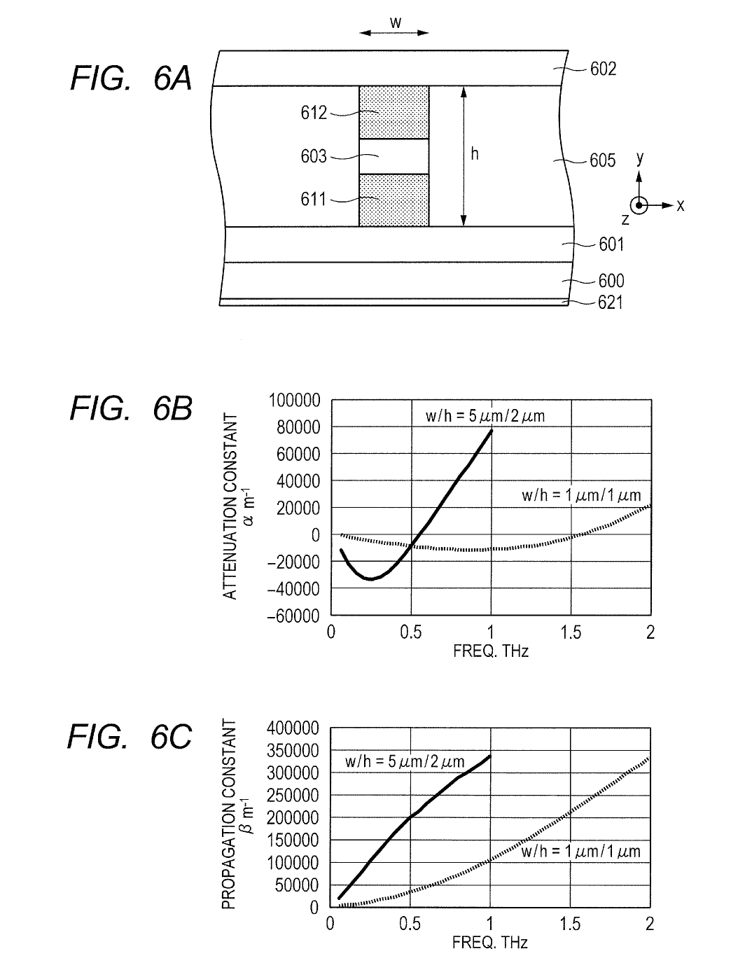

The laser device of Example 1 that will specifically be described below corresponds to the third embodiment. The laser device of this example will be described by referring to FIGS. 6A through 6C. FIG. 6A is a schematic cross sectional view of the waveguide and FIGS. 6B and 6C show the results of electric circuit calculations conducted in this example. Thus, the above-described qualitative discussions are specifically examined below.

In FIG. 6A, reference symbol 600 denotes a substrate. An InGaAs/InAlAs multiple quantum well is selected as gain medium 603 because of lattice matching relative to the InP substrate. For instance, a resonant tunneling diode formed to show a semiconductor multilayer film structure of 5.0/1.3/5.6/2.6/7.6/1.3/5.0 that extends toward the −y direction will be selected. The numerical values show the thicknesses of the component layers. The unit of the numerical values is nm. The parts that are not underlined are InGaAs wells, whereas the underlined parts are InAlAs as potential barriers. These layers are undoped layers. In other words, they are intentionally not doped with carriers. For example, n-InGaAs semiconductor film (having a thickness of 50 nm) is used for electric contact of the negative permittivity medium 611 with the resonant tunneling diode 603. N—InGaAs semiconductor film (having a thickness of 440 nm) with an electron density of 1×10¹⁹cm⁻³ is employed for most parts of the rib 611 for the purpose of reducing the conductor loss. The above description on the negative permittivity medium 611 also applies to the negative permittivity medium 612.

An Au thin film (having a thickness of 500 nm) is employed for the negative permittivity medium 601 in this example in order to reduce the conductor loss. Thus, in FIG. 6A, the part of the InP substrate where an InGaAs/InAlAs multiple quantum well is formed is already removed. Such a structure is prepared by way of an Au bonding process. More specifically, such a structure can be prepared by bonding the Au film layer 601 (having a thickness of 250 nm) formed on the InGaAs/InAlAs multiple quantum well and the Au film layer 601 (having a thickness of 250 nm) formed on the electro-conductive Si substrate 600. The InP substrate can be removed by wet etching using hydrochloric acid.

Subsequently, the semiconductor parts 611, 603 and 612 are subjected to wet etching and the waveguide is made to show a width of w=1 μm. BCB is employed for the lateral structures 605 of the gain medium 603. A thickness of h=1 μm is selected for the BCB layers. The waveguide cross sectional structure is completed by forming an Au thin film (having a thickness of 500 nm) for the negative permittivity medium 602 on the n-InGaAs 612 and the BCB 605.

When a bias voltage of 0.8 V is applied between the Au 602 that operates both as clad of negative permittivity medium and as electrode and the rear surface electrode 621 of this example, the gain that can be obtained by the resonant tunneling diode 603 is computationally determined to be about 700 cm⁻¹ for a frequency band from DC to about 1 THz. The result of Gd=−12 mS/μm² is obtained by reducing the gain to a negative differential conductance. FIG. 6B shows the results of electric circuit calculations conducted for the waveguide loss α, taking these parameters into consideration. In FIG. 6B, the net gain can be obtained in the negative region for the vertical axis. More specifically, the net gain can be obtained in the frequency region approximately from DC and 1.6 THz. For the purpose of comparison, the above results were compared with the results obtained by using an arrangement similar to that of this example except that w=5 μm and h=2 μm are selected. The oscillatable region is expanded by selecting values for w and h that reduce the ratio of w/h and the arrangement of this example is oscillatable at frequencies higher than 0.5 THz, at which the arrangement with w=5 μm and h=2 μm is not oscillatable.

For the purpose of simplicity, a Fabry-Perot cavity same as the one used in the fourth embodiment is also employed for the laser oscillator of this example. Of course, a distributed feedback type (DFB) oscillator that is well known in the field of semiconductor laser technology may be employed. Additionally, an oscillation frequency of 0.8 THz is selected so that the laser device of this example may be used as terahertz laser oscillator for color cancer detection. This is because colon cancer can be seen in clear contrast with normal colon tissues at the frequency of 0.8 THz. FIG. 6C shows the results of electric circuit calculations conducted for the magnitude of the wave-number in the direction of propagation for a surface plasmon mode, also taking the parameters same as those of FIG. 6B into consideration. From the graph of FIG. 6C, the magnitude of the wave-number β is computationally determined as 750 cm⁻¹ at the oscillation frequency of 0.8 THz, L=42 μm is selected for the length of the waveguide, which is equal to π/β, in this example. Of course, integer times of this length may be selected for L. The end facets may be formed by cleavage or by means of a process using dry etching to secure a satisfactory level of surface accuracy for electromagnetic waves between the millimeter wave range and the terahertz range (electromagnetic waves including a part of the frequency region not less than 30 GHz and not more than 30 THz).

Thus, a laser device according to the present invention is also characterized in that the value of β can be made relatively small as in this example by designing the laser device so as to provide a small w/h. Differently stated, a laser device according to the present invention can be designed with a relatively large L value and such a design is convenient for raising the output of the laser oscillator. Furthermore, the operation of taking out electromagnetic waves from an end facet of the Fabry-Perot cavity into space can be conducted efficiently. For these reasons, a cross sectional profile of a waveguide with w/h≦1 is very preferable for laser devices operating between the millimeter wave range and the terahertz range.

In the case where the gain medium is a tunneling diode as in this example, the frequency band that provides an electromagnetic wave gain extends from DC to the high frequency side. However, in the case of a quantum cascade laser, the frequency band that provides an electromagnetic wave gain is centered at several THz and shows a width of sub-terahertz, or of the Lorentzian function type. When this example is applied to a laser device having a gain medium same as the gain medium of a quantum cascade laser, the net gain is extended both to the high frequency side and also to the low frequency side. While w/h is set to be equal to 1 in this example, a value of w/h not greater than 2 (and hence the width w is not greater than twice of h) is sufficient to realize an oscillation frequency of 0.8 THz (λ=375 μm) to be used for cancer diagnosis.

A frequency band that provides a net gain and hence with which the gain exceeds the waveguide loss can be obtained for known laser devices by applying the principle of the laser devices of the above-described embodiments. For example, the oscillation wavelength band of a quantum cascade laser can be expanded and the oscillation wavelength band of a waveguide-shaped tunneling diode oscillator can be extended to the high frequency side.

A laser device according to the present invention can be expected to find applications in the fields of manufacturing control, diagnostic medical imaging, safety control and so on as an element device.

While the present invention has been described with reference to exemplary embodiments, it is to be understood the invention is not limited to the disclosed exemplary embodiments. The scope of the following claims is to be accorded the broadest interpretation so as to encompass all such modification and equivalent structures and functions.

This application claims the benefit of Japanese Patent Application No. 2013-048167, filed Mar. 11, 2013, which is hereby incorporated by reference herein in its entirety.

What is claimed is:

1. A laser device comprising a waveguide including a resonance structure for causing electromagnetic waves to resonate;
the waveguide comprising:
a gain medium for generating electromagnetic waves;
a first negative permittivity medium having a negative real part of permittivity relative to the electromagnetic waves, the first negative permittivity medium being arranged to be electrically in contact with the gain medium and;
a second negative permittivity medium having a negative real part of permittivity relative to the electromagnetic waves, the second negative permittivity medium being arranged to be electrically in contact with the gain medium at the side opposite to the first negative permittivity medium with respect to the gain medium such that the gain medium is disposed between the first and second negative permittivity mediums, the and; and
lateral structures having a positive real part of permittivity relative to the electromagnetic waves, the lateral structures being arranged to be in contact with lateral surfaces of the gain medium and sandwiched between the first and second negative permittivity mediums,
wherein the waveguide has a section in which the width w of the gain medium sandwiched between the lateral structures is not greater than twice of the thickness h of the lateral structures sandwiched between the first and second negative permittivity mediums.

2. The device according to claim 1, wherein
the waveguide has a section in which the width w of the gain medium sandwiched between the lateral structures is not greater than the thickness h of the lateral structures sandwiched between the first and second negative permittivity mediums.

3. The device according to claim 1, wherein
the width w of the gain medium sandwiched between the lateral structures is not greater than twice of the thickness h of the lateral structures sandwiched between the first and second negative permittivity mediums over the entire length of the resonance structure of the waveguide.

4. The device according to claim 3, wherein
the width w of the gain medium sandwiched between the lateral structures is not greater than the thickness h of the lateral structures sandwiched between the first and second negative permittivity mediums over the entire length of the resonance structure of the waveguide.

5. The device according to claim 1, wherein
the waveguide is provided at least with two end facets in the direction of propagation of electromagnetic waves to form the resonance structure such that standing waves are formed out of the electromagnetic waves by utilizing reflections from the end facets.

6. The device according to claim 1, wherein
the gain medium is of a resonant tunneling diode or a quantum cascade laser.

7. The device according to claim 1, wherein
each of the first and second negative permittivity mediums is formed of a densely doped semiconductor that is held in contact with the gain medium and a metal that is held in contact with the semiconductor.

8. The device according to claim 1, wherein
each of the first negative permittivity medium, the gain medium and a part of the second negative permittivity medium that is held electrically in contact with the gain medium is formed of a semiconductor.

9. The device according to claim 1, wherein
the electromagnetic waves have a frequency included in a frequency band which is not smaller than 30 GHz and not greater than 30 THz.
